(19) United States
(12) Patent Application Publication
(10) Pub. No.: US 2026/0261258 A1
(43) Pub. Date: Sep. 3, 2026

(54) DRIVING DEVICE AND DRIVING METHOD FOR SEMICONDUCTOR ELEMENT

(71) Applicant: Mitsubishi Electric Corporation, Tokyo (JP)

(72) Inventor: Yohei MITSUI, Chiyoda-ku, Tokyo (JP)

(73) Assignee: Mitsubishi Electric Corporation, Tokyo (JP)

(21) Appl. No.: 18/718,447

(22) PCT Filed: Dec. 23, 2021
(86) PCT No.: PCT/JP2021/047941

§ 371 Date: Jun. 11, 2024

(51) Int. Cl. H03K 17/0812; H02H 3/093; H03K 17/284

(52) U.S. Cl. CPC H03K 17/08122; H02H 3/093; H03K 17/08128; H03K 17/284

(57) ABSTRACT

A driving circuit outputs one of a first voltage and a second voltage to a control electrode of a semiconductor element in accordance with a gate signal that controls ON/OFF of the semiconductor element, the first voltage being a voltage for turning on the semiconductor element, the second voltage being a voltage for turning off the semiconductor element. A protection circuit performs a protection operation of turning off the semiconductor element when an abnormality occurs during an ON period of the semiconductor element. A selection circuit outputs a selection signal for switching a mode of the protection operation performed by the protection circuit, in accordance with a driving state of the semiconductor element responsive to the gate signal, by using a delayed gate signal delayed by a delay circuit.

### TECHNICAL FIELD

The present disclosure relates to a driving device and a driving method for a semiconductor element.

### BACKGROUND ART

When an arm short-circuit state occurs in a power converter including a power semiconductor element such as an insulated gate bipolar transistor (IGBT) and a metal oxide semiconductor field effect transistor (MOSFET), a large current flows through the power semiconductor element in the state where a direct current (DC) link voltage of the power converter is applied. This causes a very large loss (heat) in the semiconductor element, and thus, the semiconductor element may be thermally broken. Therefore, in order to ensure the reliability of the power converter, it is necessary to detect the short-circuit state and protect the semiconductor element before an amount of heat generation in the semiconductor element reaches a short-circuit capacity.

The short-circuit capacity and the power loss of the semiconductor element have such a trade-off relationship that the power loss during normal operation increases as the short-circuit capacity is increased. Therefore, in order to reduce the loss of the semiconductor element, it is necessary to expand a protectable range by devisal on the driving circuit side.

For example, International Publication No. 2017/026367 (PTL 1) describes a configuration in which a short-circuit protection function by a real-time current control (RTC) circuit is combined with a power switching device of a semiconductor element. The RTC circuit operates to reduce a drain current (main circuit current) of the semiconductor element by decreasing a gate-source voltage of the semiconductor element when the drain current becomes overcurrent.

The protection circuit described in PTL 1 can operate to reduce the gate-source voltage when the current in the event of a short circuit is large, thereby preventing the element from being broken due to a surge voltage.

### CITATION LIST

### Patent Literature

PTL 1: International Publication No. 2017/026367

### SUMMARY OF INVENTION

### Technical Problem

The current flowing through the semiconductor element during operation of the short-circuit protection circuit varies depending on a status of occurrence such as the timing of occurrence of a short circuit. However, in the protection circuit described in PTL 1, the contents of the protection operation against the occurrence of the short-circuit current are fixed. Therefore, it is concerned that the excessive power loss may occur depending on a status of occurrence of a short circuit.

The present disclosure has been made to solve the above-described problem, and an object thereof is to ensure the protection performance and also suppress the useless power loss as to the function of protecting a semiconductor element when an abnormality occurs.

### Solution to Problem

According to an aspect of the present disclosure, a driving device for a semiconductor element is provided. A driving device for a semiconductor element in which a current flowing from a first main electrode to a second main electrode is controlled in accordance with a voltage of a control electrode includes: a driving circuit; a protection circuit; and a selection circuit. The driving circuit outputs one of a first voltage and a second voltage to the control electrode in accordance with a gate signal that controls ON/OFF of the semiconductor element, the first voltage being a voltage for turning on the semiconductor element, the second voltage being a voltage for turning off the semiconductor element. The protection circuit performs a protection operation of turning off the semiconductor element when an abnormality occurs during an ON period of the semiconductor element. The selection circuit switches a mode of the protection operation performed by the protection circuit, in accordance with a driving state of the semiconductor element responsive to a turn-on command.

According to another aspect of the present disclosure, a driving method for a semiconductor element is provided. A driving method for a semiconductor element in which a current flowing from a first main electrode to a second main electrode is controlled in accordance with a voltage of a control electrode includes: outputting a first voltage to the control electrode in accordance with a tum-on command of the semiconductor element, the first voltage being a voltage for turning on the semiconductor element; performing a protection operation of turning off the semiconductor element when an abnormality occurs during an ON period of the semiconductor element; and switching a mode of the protection operation in accordance with a driving state of the semiconductor element responsive to the turn-on command.

### Advantageous Effects of Invention

According to the present disclosure, by switching the mode of the protection operation in accordance with the driving state of the semiconductor element responsive to the turn-on command, it is possible to ensure the protection performance and also suppress the useless power loss as to the function of protecting the semiconductor element when an abnormality occurs.

### BRIEF DESCRIPTION OF DRAWINGS

FIG. 1 is a block diagram showing a configuration of a driving device for a semiconductor element according to the present embodiment.

FIG. 2 is a circuit diagram showing a configuration example of a driving device according to a first embodiment.

FIG. 3 shows operation waveform diagrams when a semiconductor element is turned on by the driving device according to the first embodiment.

FIG. 4 is a flowchart showing a control process of a driving method for the semiconductor element according to the first embodiment.

FIG. 5 is a circuit diagram showing a configuration example of a driving device according to a second embodiment.

FIG. 6 shows operation waveform diagrams when a semiconductor element is turned on by the driving device according to the second embodiment.

FIG. 7 is a flowchart showing a control process of a driving method for the semiconductor element according to the second embodiment.

FIG. 8 is a circuit diagram showing a configuration example of a driving device according to a third embodiment.

FIG. 9 shows operation waveform diagrams when a semiconductor element is turned on by the driving device according to the third embodiment.

FIG. 10 is a circuit diagram showing a configuration example of a driving device according to a fourth embodiment.

FIG. 11 is a circuit diagram showing a configuration example of a driving device according to a fifth embodiment.

FIG. 12 shows operation waveform diagrams when a semiconductor element is turned on by the driving device according to the fifth embodiment.

### DESCRIPTION OF EMBODIMENTS

Embodiments of the present disclosure will be described in detail below with reference to the drawings, in which the same or corresponding portions are denoted by the same reference characters and description thereof will not be repeated in principle.

### First Embodiment

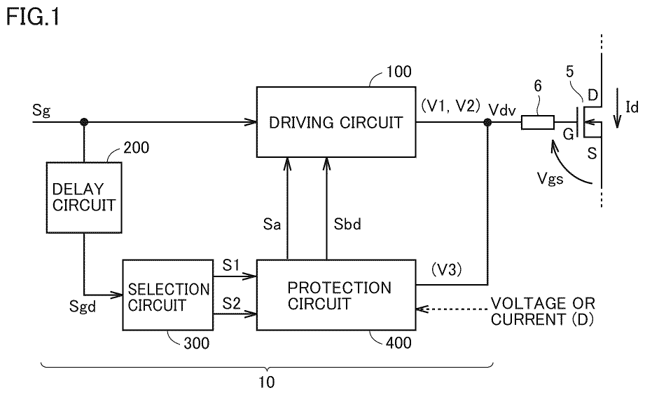

FIG. 1 is a block diagram showing a configuration of a driving device for a semiconductor element according to the present embodiment.

As shown in FIG. 1, a driving device 10 according to the present embodiment controls ON/OFF of a semiconductor element 5 in accordance with a gate signal Sg. In the example shown in FIG. 1, semiconductor element 5 is formed of a MOSFET and includes a gate (G) serving as a control electrode, a drain (D) serving as a first main electrode (high voltage side), and a source (S) serving as a second main electrode (low voltage side). In semiconductor element 5, a current flowing from the first main electrode to the second main electrode is controlled in accordance with a voltage of the control electrode. The MOSFET can, for example, be made using a semiconductor substrate such as SiC (silicon carbide), Si or GaN (gallium nitride).

A current Id (hereinafter, also referred to as “drain current Id”) flowing from the first main electrode (D) to the second main electrode (S) of semiconductor element 5 changes depending on a gate-source voltage Vgs (hereinafter, also simply referred to as “gate voltage”), which is a voltage of the control electrode with respect to the second main electrode (low voltage side).

Semiconductor element 5 is not limited to the MOSFET and can also be formed of an IGBT, a thyristor or the like as long as semiconductor element 5 is a switching element in which a current between main electrodes is controlled in accordance with a voltage of a control electrode. For example, when semiconductor element 5 is formed of an IGBT, the first main electrode is “collector” and the second main electrode is “emitter”, although the control electrode is a gate.

Driving device 10 includes a driving circuit 100, a delay circuit 200, a selection circuit 300, and a protection circuit 400. Driving device 10 outputs a driving voltage Vdv to semiconductor element 5, By controlling a gate voltage of semiconductor element 5 through a gate resistance 6 in accordance with driving voltage Vdv, the control of ON/OFF of semiconductor element 5 and the protection operation when a short-circuit current is detected are achieved.

Driving circuit 100 receives gate signal Sg as an input, and outputs one of a first voltage (ON driving voltage) V1 for turning on semiconductor element 5 and a second voltage (OFF driving voltage) V2 for turning off semiconductor element 5 to an output node Nout electrically connected to semiconductor element 5 through gate resistance 6. Gate signal Sg is set to a logic high level (hereinafter, simply referred to as “H level”) during an ON period of semiconductor element 5, and is set to a logic low level (hereinafter, simply referred to as “L level”) during an OFF period of semiconductor element 5. Furthermore, the operation of driving circuit 100 is also controlled in accordance with control signals Sa and Sbd provided from protection circuit 400 described later.

Delay circuit 200 receives gate signal Sg as an input, and outputs a delayed gate signal Sgd to which a predetermined delay time is given. Based on delayed gate signal Sgd provided from delay circuit 200, selection circuit 300 outputs selection signals S1 and S2 for switching a mode of the protection operation performed by protection circuit 400.

Protection circuit 400 has the function of detecting an abnormality of semiconductor element 5 based on a voltage or a current of the first main electrode (drain) of semiconductor element 5, and performs the protection operation for preventing semiconductor element 5 from being broken due to overcurrent by outputting control signals Sa and Sbd to driving circuit 100 or outputting a third voltage V3 to output node Nout when an abnormality is detected. As described later, protection circuit 400 operates based on selection signals S1 and S2 provided from selection circuit 300, thereby switching the protection operation in accordance with a driving state of semiconductor element 5. As described below, the driving state of semiconductor element 5 related to the protection control can be classified based on, for example, an elapsed time from the turn-on start timing at which gate signal Sg changes from the L level to the H level.

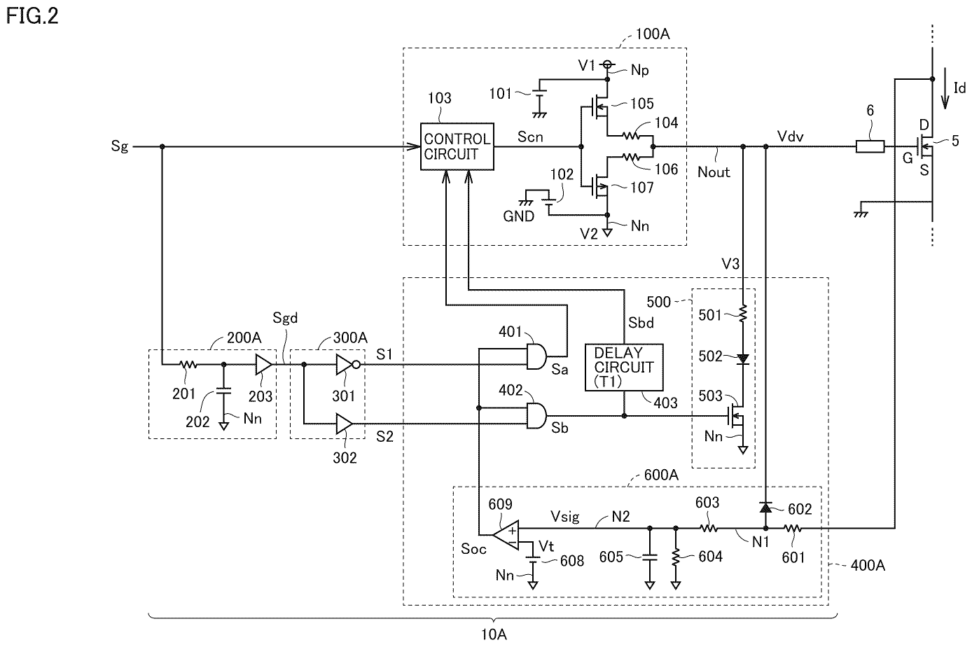

FIG. 2 is a circuit diagram showing a specific configuration of a driving device 10A according to a first embodiment.

Referring to FIG. 2, driving device 10A includes a driving circuit 100A, a delay circuit 200A, a selection circuit 300A, and a protection circuit 400A. Driving circuit 100A, delay circuit 200A selection circuit 300A, and protection circuit 400A correspond to examples of driving circuit 100, delay circuit 200, selection circuit 300. and protection circuit 400 shown in FIG. 1, respectively.

Driving circuit 100A includes a switching control circuit 103, resistance elements 104 and 106, and switching elements 105 and 107 that are turned on and off in a complementary manner.

A power supply 101 is connected between a power supply node Np and a GND node to generate the ON driving voltage (first voltage V1). Power supply node Np supplies first voltage V1. A power supply 102 is connected between the GND node and a negative power supply node Nn to generate the OFF driving voltage (second voltage V2) having a negative bias. In other words, second voltage V2 is a negative voltage (V2<0). Negative power supply node Nn supplies second voltage V2. The GND node of driving device 10A has the same potential as that of the source (second main electrode) of semiconductor element 5.

Switching element 105 formed of an N-type transistor and resistance element 104 that constitutes an ON gate resistance are connected in series between power supply node Np and output node Nout. Switching element 107 formed of a P-type transistor and resistance element 106 that constitutes an OFF gate resistance are connected in series between negative power supply node Nn and output node Nout.

Switching control circuit 103 generates a control signal Scn in accordance with gate signal Sg. Control signal Scn is set to the H level during an H-level period of gate signal Sg, and is set to the L level during an L-level period of gate signal Sg.

Control signal Scn is input to gates of the N-type transistor and the P-type transistor that form switching elements 105 and 107, respectively. As a result, switching elements 105 and 107 are turned on and off in a complementary manner. Specifically, during the H-level period of gate signal Sg, switching element 105 is turned on and switching element 107 is turned off in accordance with Scn=H. Therefore, output node Nout is connected to power supply node Np via resistance element 104 (ON gate resistance), and thus, driving voltage Vdv output from driving device 10A to output node Nout is first voltage V1.

In contrast, during the L-level period of gate signal Sg, switching element 107 is turned on and switching element 105 is turned off in accordance with Scn=L. Therefore, output node Nout is connected to negative power supply node No via resistance element 106 (OFF gate resistance), and thus, driving voltage Vdv output from driving device 10A to output node Nout is second voltage V2.

Delay circuit 200A includes a resistance element 201, a capacitor 202 and a trigger circuit 203. Gate signal Sg is input to an RC circuit formed by resistance element 201 and capacitor 202. Trigger circuit 203 generates delayed gate signal Sgd in accordance with an output voltage of the RC circuit. Delayed gate signal Sgd is a signal obtained by giving a delay time TX based on an RC time constant to gate signal Sg. In other words, delayed gate signal Sgd changes from the L level to the H level when delay time TX elapses from the timing at which gate signal Sg changes from the L level to the H level. Delay time TX can be adjusted depending on a resistance value of resistance element 201 and a capacitance value of capacitor 202.

Selection circuit 300A includes an inverting buffer 301 and a non-inverting buffer 302. Inverting buffer 301 outputs selection signal S1 obtained by inverting delayed gate signal Sgd provided from delay circuit 200, Non-inverting buffer 302 outputs selection signal S2 having the same logic level as that of delayed gate signal Sgd provided from delay circuit 200. In other words, selection signals S1 and S2 have the logic levels that are complementary to each other.

Protection circuit 400A includes a logic gate 401 that generates control signal Sa, a logic gate 402 that generates a control signal Sb, a delay circuit 403 for giving a delay time T1, a soft interruption circuit 500, and a short-circuit detection circuit 600A.

Short-circuit detection circuit 600A includes resistance elements 601, 603 and 604, a diode 602, a capacitor 605, and a comparator 609. Resistance element 601 is connected between the drain of semiconductor element 5 and a node N1. Resistance element 603 is connected between node N1 and a node N2. Resistance element 604 is connected between node N2 and negative power supply node Nn.

Diode 602 is connected between node N1 and output node Nout, and includes an anode connected to node N1 and a cathode connected to output node Nout. Capacitor 605 is connected in parallel with resistance element 604 between node N2 and negative power supply node Nn.

Comparator 609 generates a short-circuit detection signal Soc based on a result of comparison between a voltage Vsig of node N2 and a determination voltage Vt by a power supply 608 Specifically, when Vsig>Vt, a short-circuit state in which overcurrent occurs in semiconductor element 5 is detected and short-circuit detection signal Soc is set to the H level.

During the OFF period of semiconductor element 5, second voltage V2, which is a negative voltage, is supplied to output node Nout and a drain-source voltage Vds (hereinafter, also simply referred to as “drain voltage”) increases. Therefore, in short-circuit detection circuit 600A, diode 602 is brought into conduction and voltage Vsig of node N2 is clamped to a voltage equal to second voltage V2. Thus, the state of Vsig<Vt is maintained and short-circuit detection signal Soc is fixed to the L level.

Immediately after semiconductor element 5 is turned on, first voltage V1, which is a positive voltage, is supplied to output node Nout. Therefore, in short-circuit detection circuit 600A, a voltage of node N1 is the drain voltage of semiconductor element 5 divided by resistance elements 601, 603 and 604, and is clamped to first voltage V1 by diode 602. Resistance elements 603 and 604 and capacitor 605 form “filter circuit” that receives the potential of node N1 as an input voltage At this time, voltage Vsig of node N2 corresponds to an output voltage of the filter circuit. That is, in the state where output node Nout is connected to first voltage V1 and drain voltage Vds is high, voltage Vsig increases. Specifically, voltage Vsig increases with a slope based on a time constant (RC time constant) determined by resistance values of resistance elements 603 and 604 and a capacitance value of capacitor 605.

Since the drain voltage (Vds) of semiconductor element 5 is almost zero (ON voltage of the element in a steady state) in a normal turn-on state, the voltage of node N1 also decreases to around zero. Therefore, in the above-described filter circuit, charging of capacitor 605 stops, and then, discharging of capacitor 605 is started. Thus, voltage Vsig of node N2 transitions to decrease from a value (normal value Vnml) at the end of charging of capacitor 605, which is a local maximum value.

In the above-described filter circuit, when a state where drain voltage Vds is high due to the occurrence of the short-circuit state continues, charging of capacitor 608 does not stop unlike the above and the charging state continues, and thus, voltage Vsig of node N2 continues to increase without taking the above-described local maximum value. Therefore, determination voltage Vt by power supply 608 is determined to satisfy Vsig>Vt in the short-circuit state, based on first voltage V1 and the time constant of the filter circuit formed by resistance elements 603 and 604 and capacitor 605. In order to prevent erroneous determination under normal switching, determination voltage Vt is set to Vt>Vnml. As a result, short-circuit detection signal Soc is maintained in the L level during the OFF period of semiconductor element 5 and during the normal ON period, and changes to the H level when the short-circuit state occurs during the ON period.

Logic gate 401 outputs, as control signal Sa, a result of an AND operation between selection signal S1 (inverted version of delayed gate signal Sgd) provided from inverting buffer 301 and short-circuit detection signal Soc. Logic gate 402 outputs, as control signal Sb, a result of an AND operation between selection signal S2 (delayed gate signal Sgd) provided from non-inverting buffer 302 and short-circuit detection signal Soc. Delay circuit 403 outputs control signal Sbd obtained by giving predetermined delay time T1 to control signal Sb output by logic gate 402.

Control signals Sa and Sbd are input to switching control circuit 103. When control signal Sa or Sbd changes from the L level to the H level during the H-level period of gate signal Sg, switching control circuit 103 changes control signal Scn from the H level to the L level. Control signal Sb is input to soft interruption circuit 500.

Soft interruption circuit 500 includes a resistance element 501, a diode 502, and a switching element 503 formed of an N-type transistor. Resistance element 501, diode 502 and switching element 503 are connected in series between output node Nout and negative power supply node Nn. Control signal Sb is input to a gate of the N-type transistor that forms switching element 503, Diode 502 is connected, with a direction from output node Nout to negative power supply node No being defined as a forward direction.

When short-circuit detection signal Soc is in the L level, all of control signals Sa, Sb and Sbd are fixed to the L level. However, when short-circuit detection signal Soc changes from the L level to the H level, one of control signals Sa and Sb changes to the H level in response to the timing of the change, and the other of control signals Sa and Sb is maintained in the L level.

Specifically, during a time period until delay time TX by delay circuit 200A elapses from the turn-on start timing at which gate signal Sg changes from the L level to the H level (hereinafter, referred to as “turn-on period”), selection signal S1 is in the H level and selection signal S2 is in the L level. Therefore, when short-circuit detection signal Soc changes to the H level, control signal Sa changes to the H level. In response to this, switching control circuit 103 changes control signal Scn from the H level to the L level. At this time, control signal Sb is maintained in the L level, and thus, switching element 503 of soft interruption circuit 500 is maintained in the OFF state.

In contrast, during a time period after delay time TX elapses from the turn-on start timing (hereinafter, referred to as “steady ON period”), selection signal S2 is in the H level and selection signal S1 is in the L level. Therefore, when short-circuit detection signal Soc changes to the H level, control signal Sb changes to the H level In response to this, in soft interruption circuit 500, switching element 503 is turned on, and thus, a discharging path from output node Nout to negative power supply node Nn is formed. This causes a voltage drop in resistance element 501, and thus, driving voltage Vdv of output node Nout decreases from first voltage V1 to third voltage V3 (V1>V3>V2).

At the timing at which delay time T1 by delay circuit 403 elapses since control signal Sb changes to the H level, control signal Sbd is set to the H level, and in response to this, switching control circuit 103 changes control signal Scn from the H level to the L level. As a result, switching element 107 is turned on, and thus, driving voltage Vdv of output node Nout changes to second voltage V2 (V2<0). In this way, soft interruption circuit 500 operates in accordance with control signal Sb during the H-level period of control signal Scn, and thereby, soft interruption circuit 500 can temporarily decrease driving voltage Vdv to third voltage V3.

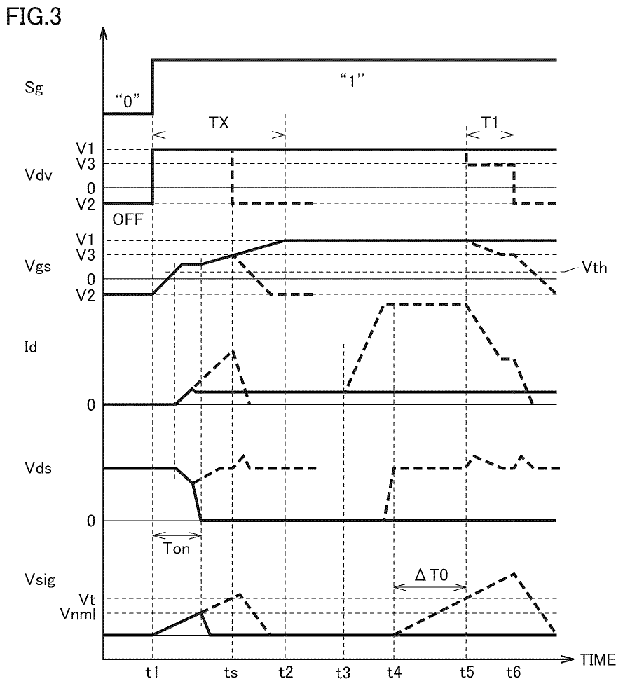

FIG. 3 shows operation waveform diagrams when the semiconductor element is turned on by the driving device according to the first embodiment. In FIG. 3, regarding the changes in voltages and current during the turn-on operation in accordance with gate signal Sg, the waveforms during normal operation are indicated by solid lines and the waveforms when a short circuit occurs are indicated by dotted lines.

Referring to FIG. 3, at time t1, gate signal Sg changes from the L level to the H level, thereby starting the turn-on operation During the OFF period of semiconductor element 5 before time t1, driving device 10A outputs second voltage V2 to the gate of semiconductor element 5 as driving voltage Vdv.

At time t1, gate signal Sg changes from the L level to the H level, and in response to this, driving voltage Vdv output from driving device 10A to the gate of semiconductor element 5 changes to first voltage V1. In response to this, gate voltage Vgs increases from second voltage V2, and after a mirror period during which the increase in voltage stops temporarily, gate voltage Vgs further increases to first voltage V1.

Drain current Id, drain voltage Vds, and voltage Vsig in short-circuit detection circuit 600A during normal tum-on will be first described with reference to the waveform diagrams indicated by the solid lines.

When gate voltage Vgs increases and exceeds a threshold voltage Vth of semiconductor element 5, drain current Id starts to flow and reaches a steady-state value at around the end of the above-described mirror period. Drain voltage Vds starts to decrease from the timing at which drain current Id starts to flow, and decreases in proportion to a rate of change in drain current Id (dId/dt) due to an parasitic inductance in the circuit. Thereafter, drain voltage Vds further decreases from around the end of the mirror period, and reaches a steady state at Vds~0.

Since driving voltage Vdv is equal to V1 (Vdv=V1) and Vds is high after time t1, voltage Vsig increases in accordance with charging of capacitor 605. Then, after the end of the mirror period, voltage Vsig decreases toward 0 in conjunction with the decrease in drain voltage Vds.

At time t2, delay time TX by delay circuit 200 has elapsed from time t1. In other words, a time period from time t1 to time t2 corresponds to the turn-on period, and after time t2, a time period until gate signal Sg changes to the L level corresponds to the steady ON period.

The operation when the short-circuit state occurs in semiconductor element 5 during the turn-on period will be first described with reference to the waveform diagrams indicated by the dotted lines in the time period from time t1 to time t2. When the short-circuit state occurs, drain current Id continues to increase even after the end of the mirror period. Since drain voltage Vds does not continue to decrease unlike during the normal operation, voltage Vsig continues to increase even after the end of the mirror period. As a result, at time ts, short-circuit detection circuit 600A detects Vsig>Vt and sets short-circuit detection signal Soc (FIG. 2) to the H level. As described above, when short-circuit detection signal Soc changes to the H level during the turn-on period, control signal Sa input to switching control circuit 103 changes to the H level.

In response to this, at time ts, switching element 107 of driving circuit 100A is turned on, and driving voltage Vdv output from driving device 10A to the gate of semiconductor element 5 changes to second voltage V2, which is a negative voltage, as indicated by the dotted line. As a result, gate voltage Vgs decreases toward second voltage V2 and drain current Id also decreases. Drain voltage Vds increases due to a surge voltage generated at the timing at which drain current Id starts to decrease, and then, reaches the OFF-time voltage. In this way, during the turn-on period, semiconductor element 5 is immediately turned off in accordance with the detection of the short-circuit state.

Next, the operation when the short-circuit state occurs in semiconductor element 5 during the steady ON period will be described with reference to the waveform diagrams indicated by the dotted lines in the time period from time t3 to time t6.

Under the state where the output of driving voltage Vdv=V1 to the gate of semiconductor element 5 is continued, the short-circuit state occurs and drain current Id starts to increase at time t3, and then, drain voltage Vds also starts to increase. In response to this, from time t4, voltage Vsig increases in conjunction with Vds, and at time t5 at which ΔT0 has elapsed from time t4, short-circuit detection circuit 600A detects Vsig>Vt and sets short-circuit detection signal Soc (FIG. 2) to the H level. As described above, when short-circuit detection signal Soc changes to the H level during the steady ON period, control signal Sb input to soft interruption circuit 500 changes to the H level.

In response to this, at time t5, switching element 503 of soft interruption circuit 500 is turned on, and thus, driving voltage Vdv output from driving device 10A to the gate of semiconductor element 5 decreases from first voltage V1 to third voltage V3. In response to this, gate voltage Vgs decreases and drain current Id also decreases. Furthermore, at time t6 at which delay time T1 by delay circuit 403 has elapsed from time t5, control signal Sbd input to switching control circuit 103 changes to the H level.

In response to this, at time to, switching element 107 of driving circuit 100A is turned on, and thus, driving voltage Vdv output from driving device 10A to the gate of semiconductor element 5 changes to second voltage V2, which is a negative voltage. As a result, semiconductor element 5 is turned off, and gate voltage Vgs decreases toward second voltage V2 and drain current Id also decreases toward 0.

At time t5 and time t6, each of which is the timing at which drain current Id starts to decrease, a surge voltage occurs in drain voltage Vds. However, after time t5 at which the short-circuit state is detected, the gate voltage is temporarily decreased to third voltage V3 and then semiconductor element 5 is turned off. Therefore, the surge voltage can be significantly suppressed, as compared with the case in which semiconductor element 5 is immediately turned off at time t5 at which the short-circuit state is detected.

Specifically, the surge voltage can be suppressed by suppressing an amount of decrease in gate voltage at time t5 and suppressing drain current Id when semiconductor element 5 is turned off at time t6.

In the case of detecting the short-circuit state during the steady ON period by monitoring the drain voltage of semiconductor element 5, drain current Id (short-circuit current) is expected to be at the level higher than that when the short circuit occurs during the turn-on period, as shown in FIG. 3. Therefore, when semiconductor element 5 is immediately turned off at the timing at which the short-circuit state is detected (time t5), the surge voltage increases and drain voltage Vds exceeds a withstand voltage, and thus, semiconductor element 5 may be broken.

In driving device 10A according to the first embodiment, at the time of detection of the short-circuit state during the steady ON period, soft interruption circuit 500 can be applied, thereby suppressing the surge voltage. Therefore, it is possible to prevent semiconductor element 5 from being broken due to the surge voltage generated by the protection operation for thermal protection in the short-circuit state, and thus, the protection function is ensured.

In contrast, at the time of detection of the short-circuit state during the turn-on period, the protection operation of turning off semiconductor element 5 is performed in the state where drain current Id is not as large as that during the steady ON period. Therefore, by immediately turning off semiconductor element 5 in response to the detection of the short-circuit state, it is possible to suppress the power loss (amount of heat generation) produced by the protection operation, while preventing semiconductor element 5 from being broken due to the surge voltage generated by the protection operation.

As described above, in the present embodiment, the tum-on period corresponds to an example of “first time period”, and the control of driving voltage Vdv after time ts corresponds to an example of “first protection operation”. Similarly, the steady ON period corresponds to an example of “second time period”, and the control of driving voltage Vdv after time t5 corresponds to an example of “second protection operation”. In addition, delay time TX by delay circuit 200A corresponds to an example of “first time”.

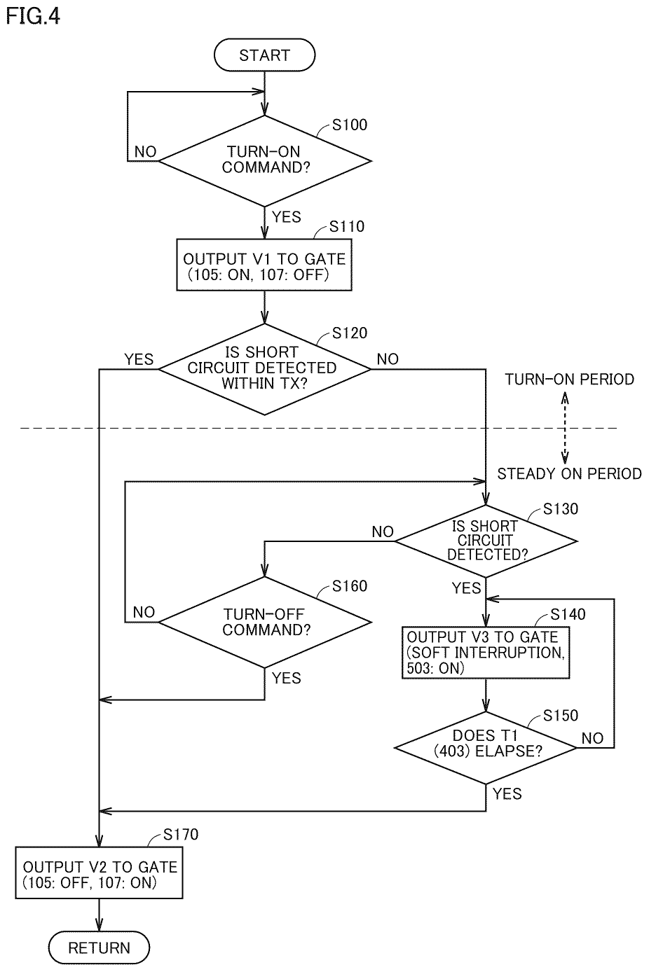

FIG. 4 is a flowchart showing a control process of a driving method for semiconductor element 5 by driving device 10A.

In step (hereinafter, simply denoted as “S”) 100, driving device 10A waits for a turn-off command in accordance with gate signal Sg during the OFF period of semiconductor element 5 in which gate signal Sg is set to the L level. When gate signal Sg changes from the L level to the H level, driving device 10A detects the turn-on command and the determination of YES is made in S100. As a result, the processing in S110 and the subsequent steps for turning on semiconductor element 5 is started. In contrast, while gate signal Sg is in the L level, the turn-on command is not detected (NO in S100) and the processing in S110 and the subsequent steps is not started.

When the turn-on command is provided (YES in S100), driving device 10A turns on switching element 105 of driving circuit 100A (FIG. 2) and turns off switching element 107 of driving circuit 100A, thereby setting driving voltage Vdv to first voltage V1 in S110. As a result, driving device 10A outputs first voltage V1 to the gate of semiconductor element 5.

Thereafter, in S120, driving device 10A determines whether the short-circuit state is detected during the tum-on period until delay time TX by delay circuit 200A elapses from the turn-on command When short-circuit detection signal Soc is set to the H level by short-circuit detection circuit 600A during the time period from time t1 to time t2 in FIG. 3, the determination of YES is made in S120 and the process proceeds to S170.

In S170, driving device 10A turns off switching element 105 of driving circuit 100A (FIG. 2) and turns on switching element 107 of driving circuit 100A, thereby setting driving voltage Vdv to second voltage V2. As a result, driving device 10A outputs second voltage V2 to the gate of semiconductor element 5 and turns off semiconductor element 5. In this way, by the operation indicated by the dotted lines in the time period from time t1 to time t2 in FIG. 3, semiconductor element 5 is immediately turned off in response to the detection of the short-circuit state.

When the short-circuit state is not detected even after delay time TX by delay circuit 200A elapses from the tum-on command in S120 (NO in S120), driving device 10A determines whether the short-circuit state is detected in S130 and S160 until the turn-off command is generated.

When the short-circuit state is not detected until time t2 in FIG. 3, i.e., when short-circuit detection signal Soc by short-circuit detection circuit 600A is maintained in the L level, the determination of NO is made in S120. In this way, the turn-on period and the steady ON period are distinguished from each other and the protection operation is switched based on the elapsed time from the start of turn-on, using delay time TX by delay circuit 200A. Delay time TX needs to be set longer than a time Ton required for drain voltage Vds to decrease to zero during normal operation. This required time Ton changes depending on the temperature and the drain current (in a steady state), and becomes longer when the temperature is low and the current is large. Therefore, by performing a switching test of semiconductor element 5, delay time TX can be set such that TX>Ton is ensured.

In addition, a short-circuit capacity Tsc [μs] is described in a datasheet and the like as one of the specifications of semiconductor element 5. Short-circuit capacity Tsc refers to a time allowance up to breakage of an element when a short-circuit current flows, and thus, delay time IX needs to be set to TX<Tsc. Therefore, delay time TX is set to Ton<TX<Tsc in accordance with the specifications and the switching test of semiconductor element 5.

When gate signal Sg changes from the H level to the L level, driving device 10A detects the turn-off command and the determination of YES is made in S160 When the short-circuit state is not detected before the turn-off command is detected (when the determination of NO in S130 is maintained), the determination of YES is made in S160 and the process proceeds to S170. In this case, driving device 10A outputs second voltage V2 to the gate of semiconductor element 5 in response to the turn-off command, thereby immediately turning off semiconductor element 5.

In contrast, when the short-circuit state is detected during the steady ON period before the turn-off command is detected, the determination of YES is made in S130 and the process proceeds to S140. In S140, driving device 10A turns on switching element 503 of soft interruption circuit 500 in accordance with control signal Sb that is set to the H level in accordance with short-circuit detection signal Soc. As a result, the operation at time t5 in FIG. 3 is implemented and driving device 10A outputs third voltage V3 to the gate of semiconductor element 5, and thereby, driving device 10A can decrease drain current Id of semiconductor element 5.

Until delay time T1 by delay circuit 403 elapses (NO in S150), driving device 10A maintains driving voltage Vdv at the third voltage during a time period corresponding to the time period from time t5 to time t6 in FIG. 3. Then, when delay time T1 by delay circuit 403 elapses (YES in S150), the process proceeds to S170 and driving device 10A outputs second voltage V2 to the gate of semiconductor element 5, thereby turning off semiconductor element 5.

In this way, when the short-circuit state is detected during the steady ON period, soft interruption is applied. The soft interruption is an operation of providing a time period in which drain current Id is decreased by decreasing the voltage output to the gate of semiconductor element 5 to third voltage V3, and then, turning off semiconductor element 5 by second voltage V2.

At this time, a time lag for discharging a gate capacitance occurs between when driving device 10A decreases driving voltage Vdv to third voltage V3 and when gate voltage Vgs of semiconductor element 5 decreases to third voltage V3. Therefore, delay time T1 by delay circuit 403 can be set in consideration of this time lag.

As described above, in driving device 10A according to the first embodiment, the driving state of semiconductor element 5 can be classified based on the elapsed time from the start of the turn-on operation, and the two types of protection operations described above can be switched. Specifically, in the short-circuit protection operation during turn-on in which a relatively small current is interrupted, semiconductor element 5 is immediately turned off and thus the power loss can be reduced, and in the short-circuit protection operation during the steady ON in which a large current is interrupted, the soft interruption is applied and thus semiconductor element 5 can be protected against the breakage caused by the surge. As a result it is possible to ensure the protection performance and also suppress the useless power loss as to the function of protecting the semiconductor element against the occurrence of the short-circuit current.

### Second Embodiment

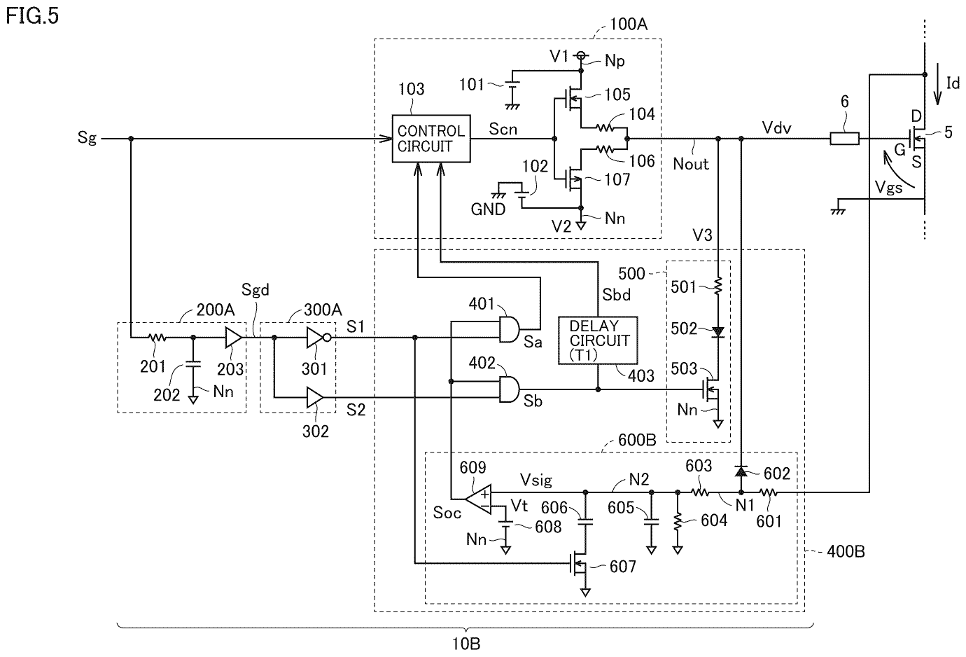

FIG. 5 is a circuit diagram showing a specific configuration of a driving device 10B according to a second embodiment.

Referring to FIG. 5, driving device 10B includes driving circuit 100A, delay circuit 200A, selection circuit 300A, and a protection circuit 400B. Driving circuit 100A, delay circuit 200A, selection circuit 300A, and protection circuit 400B correspond to examples of driving circuit 100, delay circuit 200, selection circuit 300, and protection circuit 400 shown in FIG. 1, respectively.

In short, driving device 10B is different from driving device 10A shown in FIG. 2 in that driving device 10B includes protection circuit 400B instead of protection circuit 400A. Protection circuit 400B is different from protection circuit 400A shown in FIG. 2 in that protection circuit 400B includes a short-circuit detection circuit 600B instead of short-circuit detection circuit 600A. Therefore, in driving device 10B according to the second embodiment, the configuration for generating short-circuit detection signal Soc is different from that in the first embodiment (driving device 10A), and the protection operation in accordance with short-circuit detection signal Soc is the same as that in the first embodiment.

In addition to resistance elements 601, 603 and 604, diode 602, capacitor 605. power supply 608, and comparator 609 similar to those of short-circuit detection circuit 600A (FIG. 2), short-circuit detection circuit 600B further includes a capacitor 606, and a switching element 607 formed of an N-type transistor.

Capacitor 606 and switching element 607 are connected in series between node N2 and negative power supply node Nn. Selection signal S1 provided from selection circuit 300A is input to a gate of the N-type transistor that forms switching element 607. Since selection signal S1 is an inverted signal of delayed gate signal Sgd as described above, selection signal S1 is set to the H level during the turn-on period (time t1 to time t2 in FIG. 3), and is set to the L level during the steady ON period (after time t2 in FIG. 3). Therefore, switching element 607 is turned on during the turn-on period (S1=H level), and is turned off during the steady ON period (S1=L level).

In short-circuit detection circuit 600B, a capacitance of node N2 is switched in accordance with ON/OFF of switching element 607. Specifically, during the turn-on period in which switching element 607 is turned on, a sum of the capacitances of capacitors 605 and 606 is provided to node N2. The sum of the capacitances of capacitors 605 and 606 in the second embodiment is designed to be equal to the capacitance of capacitor 606 in the first embodiment.

In contrast, during the steady ON period in which switching element 607 is turned off, only the capacitance of capacitor 606 is provided to node N2. Therefore, the capacitance of node N2 is smaller during the steady ON period than during the turn-on period. In this way, in short-circuit detection circuit 600B, “filter circuit” that receives the voltage of node N1 as an input voltage is formed by resistance elements 603 and 604 and only capacitor 605, or by resistance elements 603 and 604 and both capacitors 605 and 606.

In short-circuit detection circuit 600B, the time constant of the filter circuit that generates voltage Vsig of node N2 based on drain voltage Vds is switched between during the turn-on period and during the steady ON period such that the time constant is smaller during the steady ON period than during the turn-on period. As a result, the slope with which voltage Vsig input to comparator 609 increases in conjunction with drain voltage Vds when the short-circuit state occurs is also steeper during the steady ON period than during the turn-on period.

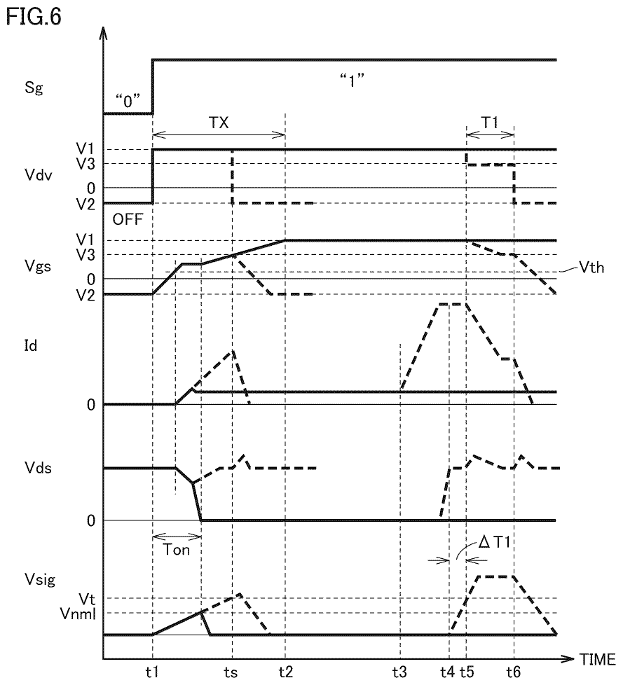

FIG. 6 shows operation waveform diagrams when the semiconductor element is turned on by the driving device according to the second embodiment Similarly to FIG. 3, in FIG. 6 as well, regarding the changes in voltages and current during the turn-on operation in accordance with gate signal Sg. the waveforms during normal operation are indicated by solid lines and the waveforms when a short circuit occurs are indicated by dotted lines.

The operation waveforms from time t1 at which the turn-on operation is started to time t2 at which the turn-on period ends in FIG. 6 are the same as those in FIG. 3.

However, after time t2 at which the turn-on period ends, switching element 607 of short-circuit detection circuit 600B is turned off, thereby increasing the speed of the increase in voltage Vsig with respect to the increase in drain voltage Vds.

Therefore, similarly to FIG. 3, when the short-circuit state occurs and drain current Id (dotted line) starts to increase at time t3, and then, drain voltage Vds (dotted line) also starts to increase, voltage Vsig increases in conjunction with Vds from time t4. At time t5 at which ΔT1 has elapsed from time t4, short-circuit detection circuit 600B detects Vsig>Vt.

As a result, short-circuit detection signal Soc (FIG. 5) is set to the H level, and thus, after time t5, the soft interruption is applied and semiconductor element 5 is turned off similarly to after time t5 in FIG. 3.

As understood from the comparison between FIG. 6 and FIG. 3, ΔT1 in FIG. 6 is shorter than ΔT0 in FIG. 3 due to a difference in speed of the increase in voltage Vsig. In other words, in the second embodiment, the occurrence of the short-circuit state can be detected in an early stage and the soft interruption can be started, as compared with the first embodiment.

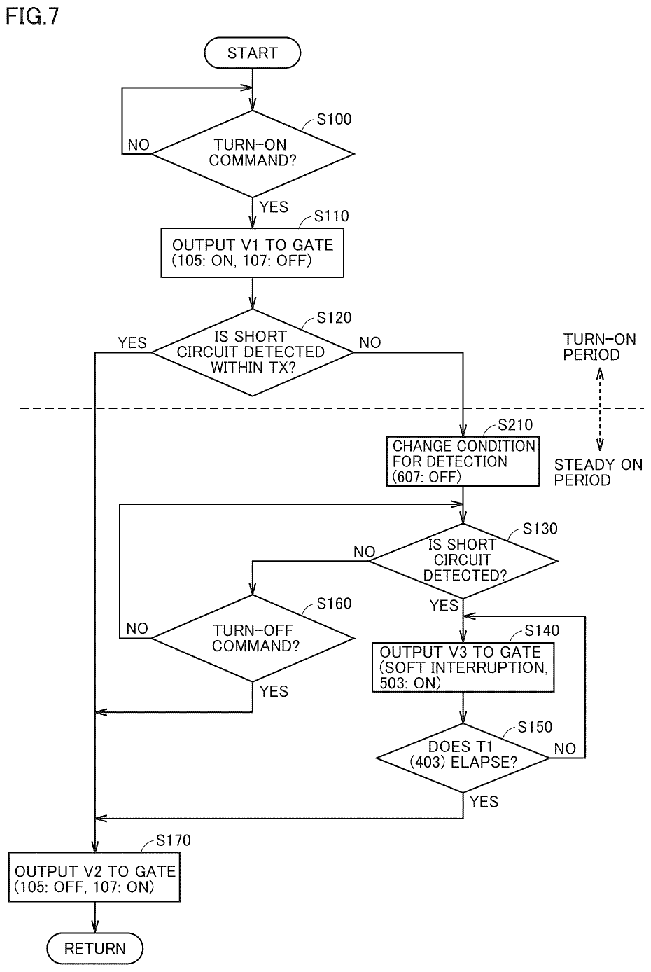

FIG. 7 is a flowchart showing a control process of a driving method for semiconductor element 5 by driving device 10B according to the second embodiment Referring to FIG. 7 and FIG. 4, driving device 10B is different in that driving device 10B further performs the processing in S210 in addition to the control process performed by driving device 10A shown in FIG. 3. When the determination of NO is made in S120, i.e., when the short-circuit state is not detected even after delay time TX by delay circuit 200A elapses from the start of the turn-on operation, driving device 10B performs the processing in S210, and then, performs the processing in S130 to S170 similar to that in FIG. 3.

In S210, driving device 10B toms off switching element 607 of short-circuit detection circuit 600B and thereby changes the condition for detection of the short-circuit state at the timing of transition from the turn-on period to the steady ON period (time t2 in FIG. 6). As a result, the speed of the increase in voltage Vsig in short-circuit detection circuit 600B is increased in the detection of the short-circuit state in S130 during the steady ON period, which makes it possible to detect the short-circuit state in an early stage, as compared with the first embodiment.

As described above, in the scheme to detect the short-circuit state based on the drain voltage of semiconductor element 5, the increase in drain voltage Vds lags behind the increase in drain current Id. Therefore, it is concerned that drain current Id is large and an amount of energy to be interrupted is large at the timing of detection of the short-circuit state. Thus, it is desirable to detect the short-circuit state as early as possible and suppress the energy to be interrupted during the steady ON period in which a large current is interrupted.

In the driving device according to the second embodiment, during the steady ON period distinguished based on the elapsed time from the start of the turn-on operation, the time constant of the filter circuit that generates the input (voltage Vsig) to comparator 609 of short-circuit detection circuit 600B can be made smaller, thereby increasing the speed of detection of the short-circuit state with respect to the increase in drain voltage Vds. As a result, the time period until the short-circuit state is detected becomes shorter, and thus, the energy to be interrupted by the protection operation during the steady ON period can be suppressed and the effect of the protection operation for preventing semiconductor element 5 from being broken can be enhanced.

Although the configuration in which the time constant of the filter circuit, i.e., the speed of increase in voltage Vsig is switched by switching the capacitance value provided to node N2 is described in the example shown in FIG. 6, the same effect can also be offered by switching a value of another passive element such as a resistance element.

### Third Embodiment

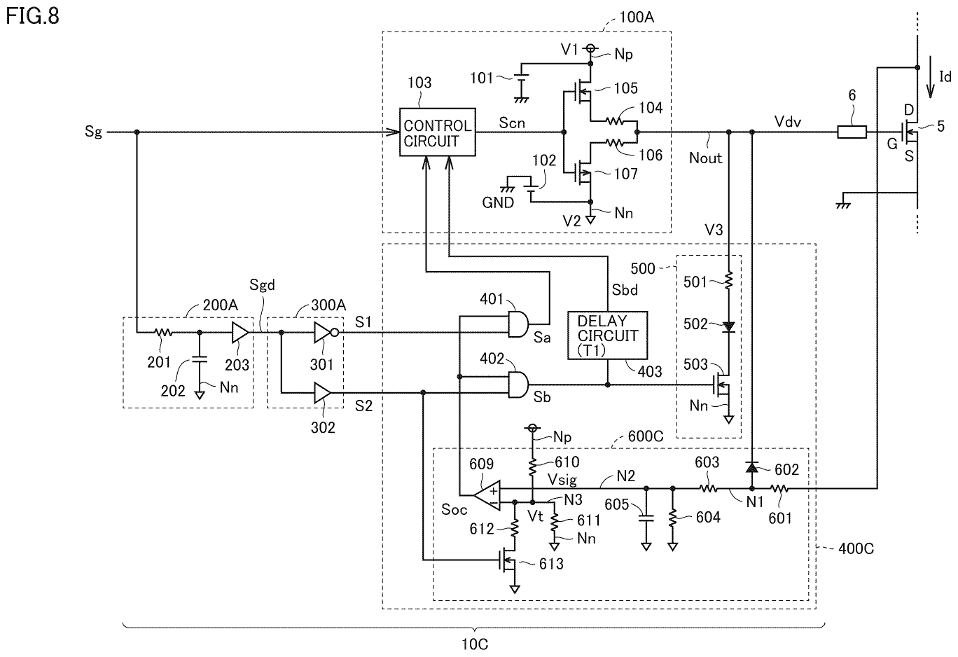

FIG. 8 is a circuit diagram showing a specific configuration of a driving device 10C according to a third embodiment.

Referring to FIG. 8, driving device 10C includes driving circuit 100A, delay circuit 200A, selection circuit 300A, and a protection circuit 400C. Driving circuit 100A, delay circuit 200A, selection circuit 300A, and protection circuit 400C correspond to examples of driving circuit 100, delay circuit 200, selection circuit 300, and protection circuit 400 shown in FIG. 1, respectively.

In short, driving device 10C is different from driving device 10A shown in FIG. 2 in that driving device 10C includes protection circuit 400C instead of protection circuit 400A. Protection circuit 400C is different from protection circuit 400A shown in FIG. 2 in that protection circuit 400C includes a short-circuit detection circuit 600C instead of short-circuit detection circuit 600A. Therefore, in driving device 10C according to the third embodiment as well, the configuration for generating short-circuit detection signal Soc is different from that in the first embodiment (driving device 10A), and the protection operation in accordance with short-circuit detection signal Soc is the same as that in the first embodiment.

In addition to resistance elements 601, 603 and 604, diode 602, capacitor 605, and comparator 609 similar to those of short-circuit detection circuit 600A (FIG. 2), short-circuit detection circuit 600C further includes resistance elements 610 to 612, and a switching element 613 formed of an N-type transistor. Furthermore, power supply 608 shown in FIG. 2 is not arranged in short-circuit detection circuit 600C.

Resistance element 610 is connected between power supply node Np and a node N3 at which determination voltage Vt is generated. Resistance element 611 is connected between node N3 and negative power supply node Nn. Resistance element 612 and switching element 613 are connected in series between node N3 and negative power supply node Nn. Selection signal S2 provided from selection circuit 300B is input to a gate of the N-type transistor that forms switching element 613. Since selection signal S2 has the same phase as that of delayed gate signal Syd as described above, selection signal S2 is set to the L level during the turn-on period (time t1 to time t2 in FIG. 3), and is set to the H level during the steady ON period (after time t2 in FIG. 3). Therefore, switching element 613 is turned on during the steady ON period (S2=H level), and is turned off during the turn-on period (S2=L level).

Short-circuit detection circuit 600C is different from short-circuit detection circuit 600A shown in FIG. 2 in that determination voltage Vt is not a constant voltage provided from power supply 608 but is switched between during the turn-on period and during the steady ON period.

In short-circuit detection circuit 600C, by switching a voltage division ratio in accordance with ON/OFF of switching element 613, determination voltage Vt is switched. Specifically, since switching element 613 is turned off during the turn-on period, (V1−V2) is divided by resistance elements 610 and 611, thereby generating determination voltage Vt.

In contrast, since switching element 613 is turned on during the steady ON period, (V1−V2) is divided by resistance element 610 and a combined resistance of resistance elements 611 and 612 connected in parallel, thereby generating determination voltage Vt. Since the combined resistance of resistance elements 611 and 612 is lower than a resistance value of resistance element 611, it is understood that determination voltage Vt is set lower during the steady ON period than during the turn-on period.

In short-circuit detection circuit 600C, voltage Vsig input to comparator 609 (+terminal) is generated by the same configuration as that of short-circuit detection circuit 600A shown in FIG. 2.

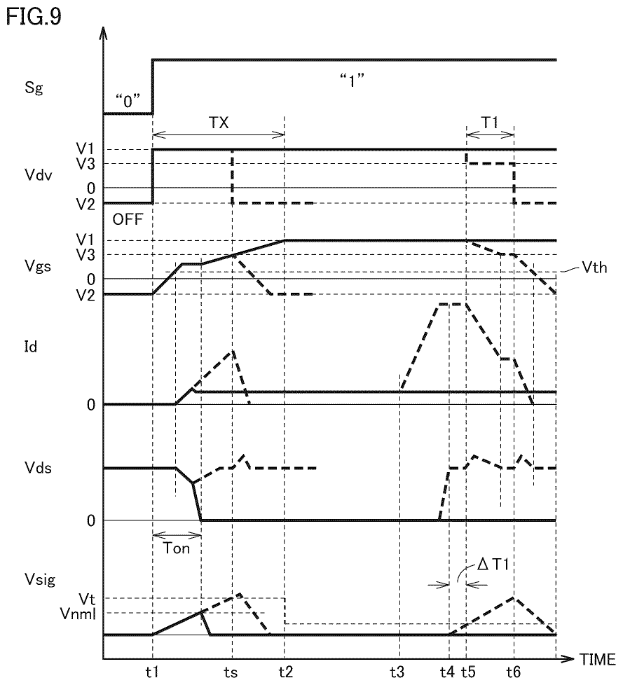

FIG. 9 shows operation waveform diagrams when the semiconductor element is turned on by the driving device according to the second embodiment. Similarly to FIGS. 3 and 6, in FIG. 9 as well, regarding the changes in voltages and current during the turn-on operation in accordance with gate signal Sg, the waveforms during normal operation are indicated by solid lines and the waveforms when a short circuit occurs are indicated by dotted lines.

The operation waveforms from time t1 at which the turn-on operation is started to time t2 at which the turn-on period ends in FIG. 9 are the same as those in FIG. 3 and 6.

However, after time t2 at which the turn-on period ends, switching element 613 of short-circuit detection circuit 600C is turned on, thereby decreasing determination voltage Vt.

Therefore, similarly to FIG. 3, when the short-circuit state occurs and drain current Id (dotted line) starts to increase at time t3, and then, drain voltage Vds (dotted line) also starts to increase, voltage Vsig increases with the same slope as that in FIG. 3 in conjunction with Vds from time t4. At time t5 at which ΔT1 has elapsed from time t4, short-circuit detection circuit 600C detects Vsig>Vt under decreased determination voltage Vt.

As a result, short-circuit detection signal Soc (FIG. 5) is set to the H level, and thus, after time t5, the soft interruption is applied and semiconductor element 5 is turned off similarly to after time t5 in FIG. 3.

As understood from the comparison between FIG. 8 and FIG. 3, by decreasing determination voltage Vt, ΔT1 in FIG. 8 becomes shorter than ΔT0 in FIG. 3, similarly to ΔT1 in FIG. 6. In other words, in the third embodiment as well, the occurrence of the short-circuit state can be detected in an early stage and the soft interruption can be started, as compared with the first embodiment.

A driving method for semiconductor element 5 by driving device 10C according to the third embodiment can be realized by turning on switching element 613 of short-circuit detection circuit 600C in S210, which is the timing of transition from the turn-on period to the steady ON period (time t2 in FIG. 6), using the flowchart shown in FIG. 7 according to the second embodiment.

Thus, in S210, the condition for detection of the short-circuit state is changed such that determination voltage Vt becomes lower than during the turn-on period. Therefore, in the detection of the short-circuit state in S130 during the steady ON period, the short-circuit state can be detected in an early stage, as compared with the first embodiment.

As described above, according to the third embodiment, during the steady ON period distinguished based on the elapsed time from the start of the turn-on operation, determination voltage Vt input to comparator 609 of short-circuit detection circuit 600C can be decreased, thereby increasing the speed of detection of the short-circuit state with respect to the increase in drain voltage Vds. As a result, the time until the short-circuit state is detected becomes shorter, and thus, the energy to be interrupted by the protection operation during the steady ON period can be suppressed and the effect of the protection operation for preventing semiconductor element 5 from being broken can be enhanced, similarly to the second embodiment.

Although the configuration in which the determination voltage is switched in accordance with the voltage division ratio by the resistance elements is described in the example shown in FIG. 8, any configuration can be applied to offer the same effect, as long as it allows the similar switching of the determination voltage

### Fourth Embodiment

In a fourth embodiment, a configuration for detecting the short-circuit state based on drain current Id will be described as another example of the method for detecting the short-circuit state of semiconductor element 5.

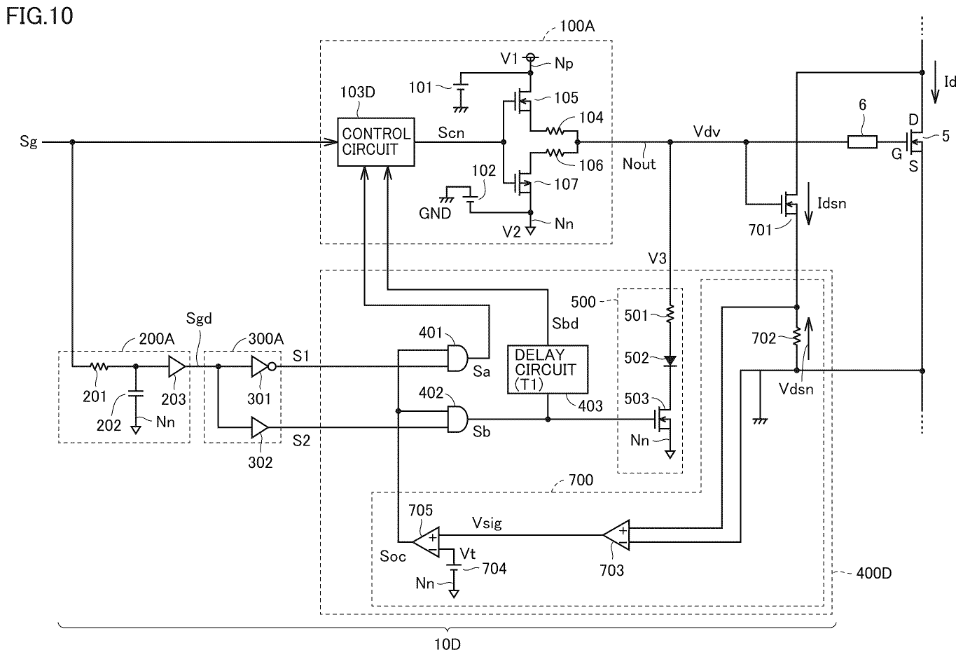

FIG. 10 is a circuit diagram showing a configuration of a driving device 10D according to the fourth embodiment.

Referring to FIG. 10, driving device 10D includes driving circuit 100A, delay circuit 200A, selection circuit 300A, and a protection circuit 400D, Driving circuit 100A, delay circuit 200A, selection circuit 300A, and protection circuit 400D correspond to examples of driving circuit 100, delay circuit 200, selection circuit 300, and protection circuit 400 shown in FIG. 1, respectively.

In short, driving device 10D is different from driving device 10A shown in FIG. 2 in that driving device 10D includes protection circuit 400D instead of protection circuit 400A. Protection circuit 400D is different from protection circuit 400A shown in FIG. 2 in that protection circuit 400D includes a short-circuit detection circuit 700 instead of short-circuit detection circuit 600A.

In other words, in driving device 10D according to the fourth embodiment, the configuration for generating short-circuit detection signal Soc is different from that in the first embodiment (driving device 10A). Short-circuit detection circuit 700 includes a resistance element 702, an amplifier 703, a power supply 704 that outputs determination voltage Vt, and a comparator 705.

Furthermore, in the fourth embodiment, a sense cell 701 for detecting the drain current is connected in parallel with semiconductor element 5. A gate of sense cell 701 is connected to the gate of semiconductor element 5, and a sense current Idsn (Idsn>Id) proportional to drain current Id of semiconductor element 5 flows through sense cell 701.

Resistance element 702 is connected in series to sense cell 701 to allow sense current Idsn to flow therethrough. As a result, a voltage Vdsn proportional to sense current Idsn, i.e., drain current Id is generated at both ends of resistance element 702. Amplifier 703 amplifies voltage Vdsn at both ends of resistance element 702 and outputs voltage Vsig. As a result, voltage Vsig is also proportional to drain current Id. In this way, an example of “voltage conversion unit” can be formed by resistance element 702 and amplifier 703.

Similarly to comparator 609 (FIG. 2), comparator 705 generates short-circuit detection signal Soc based on a result of comparison between voltage Vsig and determination voltage Vt. As a result, when Vsig>Vt, the short-circuit state in which overcurrent occurs in semiconductor element 5 is detected and short-circuit detection signal Soc is set to the H level. Since the protection operation in accordance with short-circuit detection signal Soc is the same as that in the first embodiment, detailed description will not be repeated.

In FIG. 10, the fourth embodiment in which the short-circuit state is detected based on the drain current is combined with the first embodiment. However, the fourth embodiment can also be combined with the third embodiment.

In other words, by generating determination voltage Vt in short-circuit detection circuit 700 shown in FIG. 10 similarly to the third embodiment, the third embodiment and the fourth embodiment can be combined.

### Fifth Embodiment

Although the example in which the driving state of semiconductor element 5 is classified based on the elapsed time from the turn-on start timing is described in the first to fourth embodiments, the driving state of semiconductor element 5 related to the protection control can also be classified, i.e. the above-described turn-on period and steady ON period can also be distinguished from each other, based on another parameter value such as, for example, the gate voltage (Vgs) or the gate current.

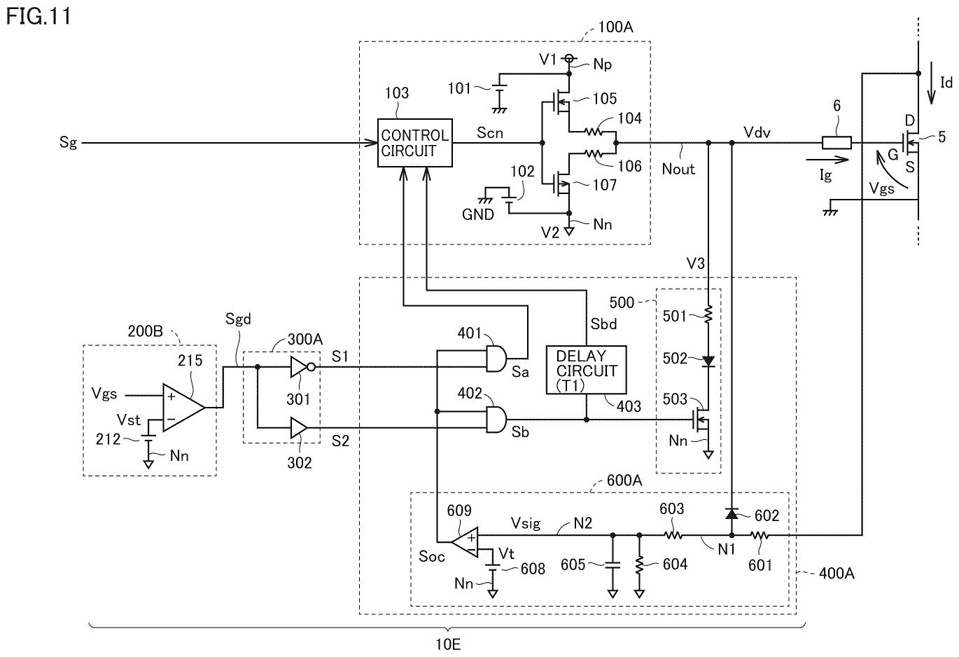

FIG. 11 is a circuit diagram showing a configuration example of a driving device 10E according to a fifth embodiment.

Referring to FIG. 11, driving device 10E includes driving circuit 100A, a delay circuit 200B, selection circuit 300A, and protection circuit 400A. Driving circuit 100A, delay circuit 200B, selection circuit 300A, and protection circuit 400B correspond to examples of driving circuit 100, delay circuit 200, selection circuit 300, and protection circuit 400 shown in FIG. 1, respectively.

In short, driving device 10E is different from driving device 10A shown in FIG. 2 in that driving device 10E includes delay circuit 200B instead of delay circuit 200A. Delay circuit 200B generates delayed gate signal Sgd equivalent to that shown in FIG. 2, using a method different from that of delay circuit 200A. In driving device 10E according to the second embodiment, the configuration for generating delayed gate signal Sgd for distinguishing the turn-on period and the steady ON period is different from that in the first embodiment (driving device 10A), and the remaining configuration and the details of the protection operations during the turn-on period and the steady ON period are the same as those in the first embodiment.

Delay circuit 200B includes a comparator 215. Comparator 215 outputs delayed gate signal Sgd based on a result of comparison between gate voltage Vgs of semiconductor element 5 and a reference value Vst corresponding to an output voltage of a power supply 212. Similarly to the first embodiment, delayed gate signal Sgd is input to inverting buffer 301 and non-inverting buffer 302 of selection circuit 300A.

By comparator 215, delayed gate signal Sgd is set to the L level when Vgs≤Vst, and is set to the H level when Vgs>Vst.

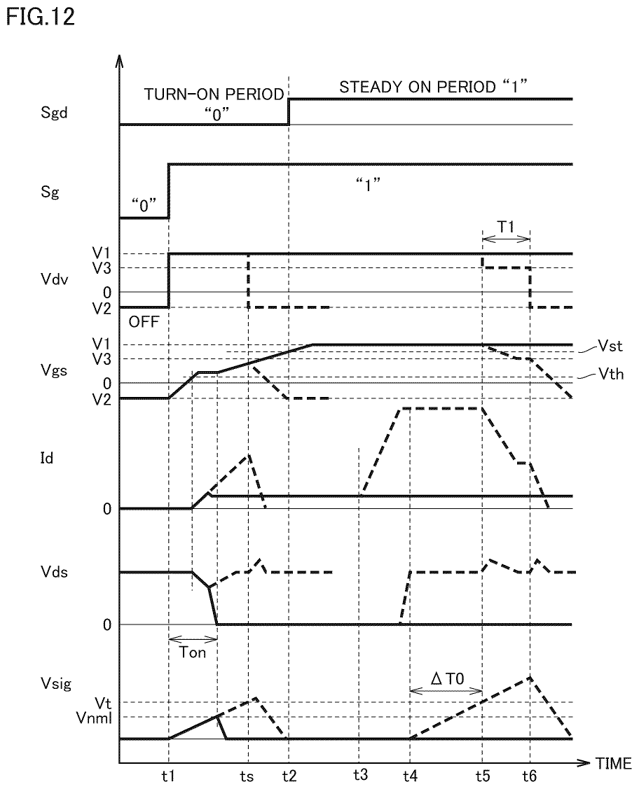

FIG. 12 shows operation waveform diagrams when the semiconductor element is turned on by driving device 10E shown in FIG. 11. The waveforms of driving voltage Vdv, gate voltage Vgs, drain current Id, drain voltage Vds, and voltage Vsig indicated by the solid lines and the dotted lines in FIG. 12 are the same as those in FIG. 3. FIG. 12 is different from FIG. 3 in that FIG. 12 shows transition of delayed gate signal Sgd in accordance with gate voltage Vgs.

Referring to FIG. 12, gate voltage Vgs starts to change from second voltage V2 toward first voltage V1 at the turn-on start timing (time t1), and increases to first voltage V1 after the mirror period.

By setting reference value Vst input to comparator 215 to a value that is slightly lower than a voltage 8 (i.e., first voltage V1) in the steady ON state of gate voltage Vgs, the turn-on period and the steady ON period can be distinguished from each other, similarly to the first to fourth embodiments. As described above, both during the normal operation and when the short-circuit state occurs, the circuit operations during the turn-on period and during the steady ON period in driving device 10E according to the fifth embodiment are the same as those in the first embodiment (driving device 10A), and thus, detailed description will not be repeated.

Since gate voltage Vgs changes with charging and discharging of the gate capacitance of semiconductor element 5 in accordance with gate current Ig shown in FIG. 10, the turn-on period and the steady ON period can also be distinguished from each other in accordance with the driving state of semiconductor element 5, based on the change in gate current Ig corresponding to the transition of gate voltage Vgs shown in FIG. 11. In this case, an input voltage proportional to gate current Ig is input to comparator 215, and reference value Vst is set in accordance with the properties of gate current Ig when semiconductor element 5 is turned on.

In the second to fourth embodiments as well, delay circuit 200B shown in FIG. 10 can be arranged instead of delay circuit 200A, and the fifth embodiment can also be combined with the second to fourth embodiments.

It is confirmatively disclosed that configurations described in the plurality of embodiments above can be appropriately combined within a technically consistent range, including combinations not directly described in the specification, and this is planned from the time of the filing of the present application.

In addition, at least some of the functions of the configuration examples of driving circuit 100, delay circuit 200, selection circuit 300, and protection circuit 400 in FIG. 1 as illustrated in the first to fifth embodiments can also be implemented by an integrated circuit (IC) such as a field programmable gate array (FPGA) having a program that can perform the equivalent operation. In other words, each circuit element described in the present embodiment can be arbitrarily implemented by at least one of hardware processing and software processing, as long as it has the equivalent function.

It should be understood that the embodiments disclosed herein are illustrative and non-restrictive in every respect. The scope of the present disclosure is defined by the terms of the claims, rather than the description above, and is intended to include any modifications within the scope and meaning equivalent to the terms of the claims.

### REFERENCE SIGNS LIST

5 semiconductor element; 10, 10A to 10E driving device; 100, 100A, 100D driving circuit; 101, 102, 608, 704 power supply; 103, 103D switching control circuit; 105, 107, 503, 607, 613 switching element; 200, 200A, 403 delay circuit; 203 trigger circuit; 300, 300A, 300B selection circuit; 301 inverting buffer; 302 non-inverting buffer; 400, 400A to 400D protection circuit; 401, 402 logic gate; 500 soft interruption circuit; 502, 602 diode; 600A to 600C, 700 short-circuit detection circuit; 609, 705 comparator; 701 sense cell; 703 amplifier; Id drain current; Idsn sense current; N1 to N3 node; Ng gate node; Nn negative power supply node; Np power supply node; S1, S2 selection signal; Sa, Sb, Sbd, Sc, Scn control signal; Sg gate signal; Sgd delayed gate signal; Soc short-circuit detection signal; T1, TX delay time; V1 first voltage; V2 second voltage; V3 third voltage; Vds drain voltage; Vdv driving voltage; Vgs gate voltage; Vt determination voltage.

1. A driving device for a semiconductor element in which a current flowing from a first main electrode to a second main electrode is controlled in accordance with a voltage of a control electrode, the driving device comprising:
a driving circuit to output one of a first voltage and a second voltage to the control electrode in accordance with a gate signal that controls ON/OFF of the semiconductor element, the first voltage being a voltage for turning on the semiconductor element, the second voltage being a voltage for turning off the semiconductor element;
a protection circuit to perform a protection operation of turning off the semiconductor element when an abnormality occurs during an ON period of the semiconductor element; and
a selection circuit to switch a mode of the protection operation performed by the protection circuit, in accordance with a driving state of the semiconductor element responsive to a turn-on command, wherein
the selection circuit outputs a selection signal to the protection circuit such that the protection circuit performs a first protection operation when an elapsed time from a timing at which turn-on of the semiconductor element is started in accordance with the gate signal is equal to or less than a predetermined first time in the ON period, and the protection circuit performs a second protection operation when the elapsed time exceeds the first time in the ON period,
in a first time period in which the first protection operation is instructed by the selection signal, the protection circuit controls the driving circuit such that the driving circuit outputs the second voltage to the control electrode in response to detection of the abnormality of the semiconductor element, and
in a second time period in which the second protection operation is instructed by the selection signal, the protection circuit controls the driving circuit such that a time period in which a third voltage is output to the control electrode is provided and then the driving circuit outputs the second voltage to the control electrode in response to detection of the abnormality of the semiconductor element, and
the third voltage is a voltage between the first voltage and the second voltage.

2. (canceled)

3. A driving device for a semiconductor element in which a current flowing from a first main electrode to a second main electrode is controlled in accordance with a voltage of a control electrode, the driving device comprising:
a driving circuit to output one of a first voltage and a second voltage to the control electrode in accordance with a gate signal that controls ON/OFF of the semiconductor element, the first voltage being a voltage for turning on the semiconductor element, the second voltage being a voltage for turning off the semiconductor element;
a protection circuit to perform a protection operation of turning off the semiconductor element when an abnormality occurs during an ON period of the semiconductor element; and
a selection circuit to switch a mode of the protection operation performed by the protection circuit, in accordance with a driving state of the semiconductor element responsive to a turn-on command, wherein
the selection circuit outputs a selection signal to the protection circuit such that the protection circuit performs a first protection operation until a voltage or a current of the control electrode reaches a predetermined reference value in the ON period, and the protection circuit performs a second protection operation after the voltage or the current of the control electrode reaches the reference value,
in a first time period in which the first protection operation is instructed by the selection signal, the protection circuit controls the driving circuit such that the driving circuit outputs the second voltage to the control electrode in response to detection of the abnormality of the semiconductor element, and
in a second time period in which the second protection operation is instructed by the selection signal, the protection circuit controls the driving circuit such that a time period in which a third voltage is output to the control electrode is provided and then the driving circuit outputs the second voltage to the control electrode in response to detection of the abnormality of the semiconductor element, and
the third voltage is a voltage between the first voltage and the second voltage.

4. The driving device according to claim 1, wherein
the protection circuit includes a soft interruption circuit to form a discharge path from the control electrode via a resistance element, and
in the second protection operation, the protection circuit provides the time period in which the third voltage is output to the control electrode, by actuating the soft interruption circuit to form the discharge path in response to detection of the abnormality of the semiconductor element.

5. The driving device according to claim 1, wherein
the protection circuit includes a short-circuit detection circuit to detect a short-circuit state of the semiconductor element based on a current or a voltage of the first main electrode, and
when the short-circuit state is detected by the short-circuit detection circuit, the protection circuit detects the abnormality of the semiconductor element and performs the first protection operation or the second protection operation corresponding to the selection signal provided from the selection circuit.

6. The driving device according to claim 5, wherein
the short-circuit detection circuit includes:
a filter circuit that receives, as an input voltage, a voltage of a node at which a divided voltage of the voltage of the first main electrode is generated; and
a comparator to compare an output voltage of the filter circuit and a determination voltage, and
when the output voltage is higher than the determination voltage, the short-circuit detection circuit detects the short-circuit state.

7. The driving device according to claim 6, wherein
a time constant of the filter circuit is switched in accordance with the selection signal provided from the selection circuit, such that the time constant is smaller in the second time period than in the first time period.

8. The driving device according to claim 5, wherein
the short-circuit detection circuit includes:
a current/voltage conversion unit that outputs a voltage corresponding to the current of the first main electrode; and
a comparator to compare an output voltage of the current/voltage conversion unit and a determination voltage, and
when the output voltage is higher than the determination voltage, the short-circuit detection circuit detects the short-circuit state.

9. The driving device according to claim 6, wherein
the determination voltage is switched in accordance with the selection signal provided from the selection circuit, such that the determination voltage is lower in the second time period than in the first time period.

10. The driving device according to claim 5, wherein
the short-circuit detection circuit is configured such that a detection speed of the short-circuit state with respect to an increase in the current or the voltage of the first main electrode in the second time period is higher than the detection speed in the first time period.

11-15. (canceled)

16. The driving device according to claim 3, wherein
the protection circuit includes a soft interruption circuit to form a discharge path from the control electrode via a resistance element, and
in the second protection operation, the protection circuit provides the time period in which the third voltage is output to the control electrode, by actuating the soft interruption circuit to form the discharge path in response to detection of the abnormality of the semiconductor element.

17. The driving device according to claim 3, wherein
the protection circuit includes a short-circuit detection circuit to detect a short-circuit state of the semiconductor element based on a current or a voltage of the first main electrode, and
when the short-circuit state is detected by the short-circuit detection circuit, the protection circuit detects the abnormality of the semiconductor element and performs the first protection operation or the second protection operation corresponding to the selection signal provided from the selection circuit.

18. The driving device according to claim 17, wherein
the short-circuit detection circuit is configured such that a detection speed of the short-circuit state with respect to an increase in the current or the voltage of the first main electrode in the second time period is higher than the detection speed in the first time period.

19. A driving method for a semiconductor element in which a current flowing from a first main electrode to a second main electrode is controlled in accordance with a voltage of a control electrode, the driving method comprising:
outputting a first voltage to the control electrode in accordance with a turn-on command of the semiconductor element, the first voltage being a voltage for turning on the semiconductor element;
performing a protection operation of turning off the semiconductor element when an abnormality occurs during an ON period of the semiconductor element; and
switching a mode of the protection operation in accordance with a driving state of the semiconductor element responsive to the turn-on command, wherein
the performing a protection operation includes:
performing a first protection operation in a first time period of the ON period in which an elapsed time from a timing at which turn-on of the semiconductor element is started in accordance with a gate signal that controls ON/OFF of the semiconductor element is equal to or less than a predetermined first time, the first protection operation being an operation of outputting a second voltage for turning off the semiconductor element to the control electrode in response to detection of the abnormality of the semiconductor element; and
performing a second protection operation in a second time period of the ON period in which the elapsed time exceeds the first time, the second protection operation being an operation of providing a time period in which a third voltage is output to the control electrode and then outputting the second voltage to the control electrode in response to detection of the abnormality of the semiconductor element, and
the third voltage is a voltage between the first voltage and the second voltage.

20. A driving method for a semiconductor element in which a current flowing from a first main electrode to a second main electrode is controlled in accordance with a voltage of a control electrode, the driving method comprising:
outputting a first voltage to the control electrode in accordance with a turn-on command of the semiconductor element, the first voltage being a voltage for turning on the semiconductor element;
performing a protection operation of turning off the semiconductor element when an abnormality occurs during an ON period of the semiconductor element; and
switching a mode of the protection operation in accordance with a driving state of the semiconductor element responsive to the turn-on command, wherein
the performing a protection operation includes:
performing a first protection operation in a first time period of the ON period until a voltage or a current of the control electrode reaches a predetermined reference value, the first protection operation being an operation of outputting a second voltage for turning off the semiconductor element to the control electrode in response to detection of the abnormality of the semiconductor element; and
performing a second protection operation in a second time period of the ON period after the voltage or the current of the control electrode reaches the reference value, the second protection operation being an operation of providing a time period in which a third voltage is output to the control electrode and then outputting the second voltage to the control electrode in response to detection of the abnormality of the semiconductor element, and
the third voltage is a voltage between the first voltage and the second voltage.

21. The driving method according to claim 19, wherein
the performing a protection operation includes detecting a short-circuit state of the semiconductor element based on a current or a voltage of the first main electrode, and
when the short-circuit state is detected, the abnormality of the semiconductor element is detected and the first protection operation or the second protection operation is performed.

22. The driving method according to claim 21, wherein
the performing a protection operation further includes increasing a detection speed of the short-circuit state with respect to an increase in the current or the voltage of the first main electrode when the first time period ends.

23. The driving method according to claim 20, wherein
the performing a protection operation includes detecting a short-circuit state of the semiconductor element based on a current or a voltage of the first main electrode, and
when the short-circuit state is detected, the abnormality of the semiconductor element is detected and the first protection operation or the second protection operation is performed.

24. The driving method according to claim 23, wherein
the performing a protection operation further includes increasing a detection speed of the short-circuit state with respect to an increase in the current or the voltage of the first main electrode when the first time period ends.
